(19) United States
(12) Patent Application Publication
(10) Pub. No.: US 2024/0422957 A1
(43) Pub. Date: Dec. 19, 2024

(54) SEMICONDUCTOR STRUCTURE AND METHOD FOR FORMING SAME

(71) Applicant: CXMT CORPORATION, Hefei (CN)

(72) Inventors: Xinman CAO, Hefei (CN); Chuang SONG, Hefei (CN)

(21) Appl. No.: 18/822,446

(22) Filed: Sep. 2, 2024

Related U.S. Application Data
(63) Continuation of application No. PCT/CN2023/131404, filed on Nov. 14, 2023.

(30) Foreign Application Priority Data
Jan. 18, 2023 (CN) 202310092863.5

(51) Int. Cl. H10B 12/00

(52) U.S. Cl. CPC H10B 12/0335; H10B 12/315

(57) ABSTRACT

The present disclosure relates to a semiconductor structure and a method for forming the same. The semiconductor structure includes a substrate, multiple conductive structures, multiple isolation structures, and a barrier layer. The multiple conductive structures are arranged at intervals on the substrate. The isolation structure is disposed between adjacent conductive structures. The barrier layer is disposed on the conductive structure. The isolation structure is higher than the barrier layer.

### CROSS-REFERENCE TO RELATED APPLICATIONS

This application is a continuation application of International Patent Application No. PCT/CN2023/131404, filed on Nov. 14, 2023, which is based on and claims priority to the Chinese Patent Application No. 202310092863.5, filed on Jan. 18, 2023, and entitled “SEMICONDUCTOR STRUCTURE AND METHOD FOR FORMING SAME”, which is incorporated herein by reference in its entirety.

### TECHNICAL FIELD

The present disclosure relates to the field of semiconductor manufacturing technologies, and in particular, to a semiconductor structure and a method for forming the same.

### BACKGROUND

A dynamic random access memory (DRAM) is a semiconductor device commonly used in an electronic device such as a computer, and includes multiple memory cells, each memory cell typically including a transistor and a capacitor. A gate of the transistor is electrically connected to a word line, a source is electrically connected to a bit line, and a drain is electrically connected to a capacitor. The voltage on the word line can control the transistor to be turned on or off, allowing data stored in the capacitor to be read via the bit line, or data to be written into the capacitor.

In a manufacturing process of a semiconductor structure such as the DRAM, it is necessary to form contact plugs with high aspect ratios to either extract signals from or introduce signals into conductive structures. However, in an actual semiconductor process technology, the high aspect ratio of a through-hole for forming a contact plug often leads to a distortion such as tilting or bending of the through-hole during etching, or misalignment causes shifts in the positions of the through-holes. The distortion or a shift of the through-hole reduces a distance between the contact plug formed within the through-hole and a surrounding conductive structure. When a voltage signal is applied to the contact plug, a leakage current easily occurs between the contact plug and the surrounding conductive structure, and in a severe case, the conductive structure is burnt out.

Therefore, how to reduce leakage issues within semiconductor structures to improve their performance and yield is a pressing technical challenge to be currently addressed.

### SUMMARY

Some embodiments of the present disclosure provide a semiconductor structure and a method for forming the same, so as to reduce leakage issues within semiconductor structures, thereby improving performance and yield of the semiconductor structures.

According to some embodiments, the present disclosure provides a semiconductor structure, including:
a substrate;
multiple conductive structures, the multiple conductive structures being arranged at intervals on the substrate;
multiple isolation structures, the isolation structure being disposed between adjacent conductive structures; and
a barrier layer, the barrier layer being disposed on the conductive structure, and
the isolation structure being higher than the barrier layer.

In some embodiments, the semiconductor structure further includes:
multiple contact plugs, the multiple contact plugs being in a one-to-one correspondence with the multiple conductive structures, and the contact plugs running through a gap between two adjacent isolation structures and being electrically connected to the conductive structures.

In some embodiments, a bottom surface of the contact plug is in electrical contact connection with a top surface of the conductive structure; and
the width of the contact plug is less than the width of the gap between the two adjacent isolation structures.

In some embodiments, a projection of the contact plug on a top surface of the substrate is located within a projection of the gap between two adjacent isolation structures on the top surface of the substrate.

In some embodiments, the contact plug includes:
a first portion located on the isolation structure, the first portion covering at least a part of a top surface of the isolation structure; and
a second portion protruding over a bottom surface of the first portion, the second portion covering a sidewall of the isolation structure and the top surface of the conductive structure.

In some embodiments, the width of the second portion is less than the width of the first portion, and a part of a sidewall of the second portion is flush with a part of a sidewall of the first portion.

In some embodiments, the contact plug extends in a direction in which the substrate points to the conductive structure; or
an extension direction of the contact plug obliquely intersects the direction in which the substrate points to the conductive structure.

In some embodiments, a distance between the top surface of the isolation structure and the top surface of the conductive structure is 10 nm to 100 nm in the direction in which the substrate points to the conductive structure.

In some embodiments, the semiconductor structure further includes:
an isolation layer disposed on the barrier layer.

The contact plug continuously penetrates the isolation layer and the barrier layer.

In some embodiments, the barrier layer is made of a nitride material.

According to some other embodiments, the present disclosure further provides a method for forming a semiconductor structure, including the steps as follows.

A substrate is provided.

Multiple conductive structures arranged at intervals on the substrate are formed, and a barrier layer on the conductive structures is formed.

Multiple isolation structures are formed on the substrate. The isolation structure is disposed between adjacent conductive structures, and the isolation structure is higher than the barrier layer.

In some embodiments, the step in which multiple conductive structures arranged at intervals on the substrate are formed, and a barrier layer on the conductive structures is formed includes the specific steps as follows.

A conductive material layer covering a top surface of the substrate is formed.

An initial barrier layer covering the conductive material layer is formed.

The initial barrier layer and the conductive material layer are etched to form multiple first trenches arranged at intervals in a first direction and penetrating the conductive material layer and the initial barrier layer in a second direction. The multiple first trenches separate the conductive material layer into multiple independent conductive structures arranged at intervals in the first direction, and separate the initial barrier layer into multiple independent barrier layers arranged at intervals in the first direction, the first direction is parallel to the top surface of the substrate, and the second direction is perpendicular to the top surface of the substrate.

In some embodiments, the step in which multiple first trenches arranged at intervals in a first direction and penetrating the conductive material layer and the initial barrier layer in a second direction are formed includes the specific steps as follows.

An initial first isolation layer covering a top surface of the initial barrier layer is formed.

The initial first isolation layer, the initial barrier layer, and the conductive material layer are etched to form the first trenches continuously penetrating the initial first isolation layer, the initial barrier layer, and the conductive material layer in the second direction. The multiple first trenches separate the initial first isolation layer into multiple independent first isolation layers arranged at intervals in the first direction.

In some embodiments, the thickness of the initial first isolation layer in the second direction is greater than or equal to the thickness of the initial barrier layer in the second direction.

In some embodiments, the initial first isolation layer is made of an oxide material and the initial barrier layer is made of a nitride material.

In some embodiments, the total thickness of the initial first isolation layer and the initial barrier layer in the second direction is 10 nm to 100 nm.

In some embodiments, the step in which multiple isolation structures are formed on the substrate includes the specific step as follows.

The multiple first trenches are filled with an insulation material to form the multiple isolation structures one by one in the multiple first trenches. A top surface of the isolation structure is flush with a top surface of the first isolation layer or a top surface of the isolation structure is higher than a top surface of the first isolation layer.

In some embodiments, that the multiple isolation structures are formed one by one in the multiple first trenches includes the specific steps as follows.

The insulation material continuously and fully filling the multiple first trenches and covering the top surface of the first isolation layer is formed.

The insulation material covering the top surface of the first isolation layer is removed, and the insulation material is retained in the first trenches as the isolation structure.

In some embodiments, after the multiple isolation structures are formed on the substrate, the method further includes the step as follows.

Multiple contact plugs in a one-to-one correspondence with the multiple conductive structures are formed. The contact plug at least partially runs through a gap between two adjacent isolation structures and is electrically connected to the conductive structure.

In some embodiments, the step in which multiple contact plugs in a one-to-one correspondence with the multiple conductive structures are formed includes the specific steps as follows.

A second isolation layer covering a top surface of the isolation structure and a top surface of the first isolation layer is formed.

A through-hole penetrating at least the second isolation layer, the first isolation layer, and the barrier layer in the second direction is formed. The bottom of the through-hole exposes the conductive structure.

The contact plug fully filling the through-hole is formed.

In some embodiments, the through-hole exposes the top surface of the conductive structure or the through-hole extends to an interior of the conductive structure.

The width of the through-hole is less than the width of the gap between the two adjacent isolation structures.

In some embodiments, a bottom surface of the through-hole is flat, and a projection of the through-hole on the top surface of the substrate is located within a projection of the gap between two adjacent isolation structures on the top surface of the substrate.

In some embodiments, the through-hole extends in the second direction; or
the through-hole extends in a third direction, and the third direction obliquely intersects the second direction.

In some embodiments, the step in which a through-hole penetrating at least the second isolation layer, the first isolation layer, and the barrier layer in the second direction is formed includes the specific step as follows.

The second isolation layer, the first isolation layer, and the barrier layer are etched to form the through-hole including a first sub-through-hole and a second sub-through-hole. A bottom surface of the first sub-through-hole exposes the top surface of the isolation structure, the second sub-through-hole protrudes over the bottom surface of the first sub-through-hole in the second direction and is in communication with the first sub-through-hole, and the second sub-through-hole exposes a sidewall of the isolation structure and the conductive structure.

In some embodiments, the width of the first sub-through-hole is greater than the width of the second sub-through-hole, and a part of a sidewall of the second sub-through-hole is flush with a part of a sidewall of the first sub-through-hole.

According to the semiconductor structure and the method for forming the same provided in some embodiments of the present disclosure, multiple independent isolation structures arranged at intervals are disposed on the substrate, each of the isolation structures is located between two adjacent conductive structures, and the isolation structure is higher than a barrier layer disposed on the conductive structure, so that when a contact plug electrically connected to the conductive structure is formed, a position shift of the contact plug caused by misalignment or a distortion can be reduced through the isolation structure. In this way, a distance between the contact plug electrically connected to one of the two adjacent conductive structures and the other conductive structure is increased, thereby reducing leakage issues between the contact plug electrically connected to one of the conductive structures and the other conductive structure, and further reducing burn-out of the semiconductor structure and improving performance and yield of the semiconductor structure.

### BRIEF DESCRIPTION OF DRAWINGS

FIG. 1 is a schematic structural diagram of a semiconductor structure according to a specific implementation of the present disclosure;

FIG. 2 is another schematic structural diagram of a semiconductor structure according to a specific implementation of the present disclosure;

FIG. 3 is a schematic diagram of a relative position relationship between a contact plug, a conductive structure, and an isolation structure in FIG. 2;

FIG. 4 is a flowchart of a method for forming a semiconductor structure according to a specific implementation of the present disclosure; and

FIG. 5 to FIG. 10 are schematic cross-sectional views of main techniques in a process of forming a semiconductor structure according to a specific implementation of the present disclosure.

### DESCRIPTION OF EMBODIMENTS

Specific implementations of a semiconductor structure and a method for forming the same provided in the present disclosure are described below in detail with reference to accompanying drawings.

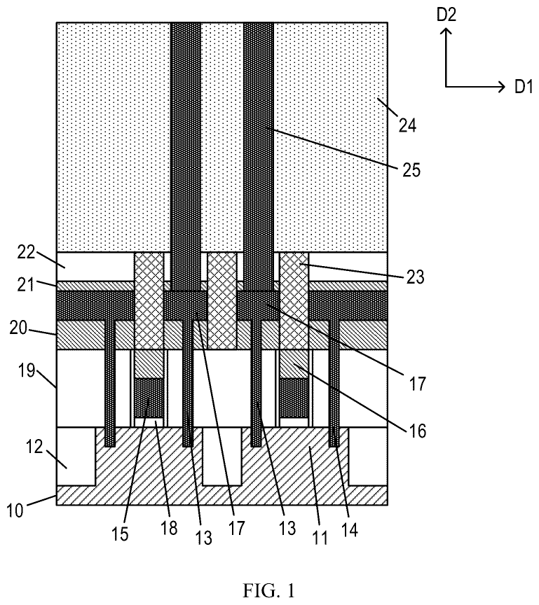

A specific implementation provides a semiconductor structure. FIG. 1 is a schematic structural diagram of a semiconductor structure according to a specific implementation of the present disclosure. As shown in FIG. 1, the semiconductor structure includes:
a substrate 10;
multiple conductive structures 17, the multiple conductive structures 17 being arranged at intervals on the substrate 10;
multiple isolation structures 23, the isolation structure 23 being disposed between adjacent conductive structures 17; and
a barrier layer 21, the barrier layer 21 being disposed on the conductive structure 17.

In some embodiments, the semiconductor structure further includes:
multiple contact plugs 25, the multiple contact plugs 25 being in a one-to-one correspondence with the multiple conductive structures 17, and the contact plugs 25 running through a gap between two adjacent isolation structures 23 and being electrically connected to the conductive structures 17.

The semiconductor structure in this specific implementation may be but is not limited to a dynamic random access memory (DRAM). The substrate 10 may be but is not limited to a silicon substrate. In this specific implementation, an example in which the substrate 10 is a silicon substrate is used for description. In another embodiment, the substrate 10 may alternatively be a semiconductor substrate such as gallium nitride, gallium arsenide, gallium carbide, silicon carbide, or silicon-on-insulator (SOI). In an example, the multiple conductive structures 17 are arranged at intervals on a top surface of the substrate 10 in a first direction D1, the conductive structures 17 are located on the top surface of the substrate 10 in a second direction D2, the first direction D1 is parallel to the top surface of the substrate 10, the second direction D2 is parallel to the top surface of the substrate 10, and the top surface of the substrate 10 is a surface of the substrate 10 facing toward the conductive structures 17. In an example in which the semiconductor structure is a DRAM, the substrate 10 includes at least multiple active regions 11 arranged at intervals in the first direction D1 and a shallow trench isolation region 12 located between adjacent active regions 11, and the shallow trench isolation region 12 is configured to electrically isolate the adjacent active regions 11. The active region 11 includes a channel region, and a source region and a drain region that are located on two opposite sides of the channel region in the first direction D1. The top surface of the substrate 10 further has a word line structure, and a first contact pillar 13 and a second contact pillar 14 that are located on two opposite sides of the word line structure in the first direction D1. The word line structure includes a gate dielectric layer 18 covering a top surface of the channel region, a word line conductive layer 15 located on a top surface of the gate dielectric layer 18, and a word line cap layer 16 located on a top surface of the word line conductive layer 15. The first contact pillar 13 is in electrical contact connection with the source region, and the second contact pillar 14 is in electrical contact connection with the drain region. For two adjacent active regions in the substrate 10 in the first direction D1, the drain region in one active region is adjacent to the drain region in the other active region. The substrate 10 further includes a first dielectric layer 19 covering the first contact pillar 13, the second contact pillar 14, and the word line structure, and a second dielectric layer 20 covering a top surface of the first dielectric layer 19. In an example, the first dielectric layer 19 may be made of an oxide material (e.g., silicon dioxide), and the second dielectric layer 20 may be made of a nitride material (e.g., silicon nitride). In this specific implementation, an example in which the conductive structure 17 is a capacitor contact pad that is located on the top surface of the second dielectric layer 20 and that is in electrical contact connection with the first contact pillar 13 directly is used for description. In an example, multiple contact plugs 25 are arranged at intervals in the first direction D1, the multiple contact plugs 25 are in a one-to-one correspondence with the multiple conductive structures 17, the contact plugs 25 at least partially run through, in the second direction D2, the gap between the two adjacent isolation structures 23 in the first direction D1, and are electrically connected to the conductive structures 17.

The multiple barrier layers 21 cover the multiple conductive structures 17 one by one. The barrier layer 21 can prevent oxidation and electrochemical reaction from occurring on the conductive structure 17, thereby ensuring morphology and performance of the conductive structure. In addition, the barrier layer 21 can also serve as an etch barrier layer for forming the contact plug 25, so as to ensure morphology and a feature size of the contact plug 25.

The isolation structure 23 being higher than the barrier layer 21 means that the isolation structure 23 protrudes from the conductive structure 17 in the second direction D2, that is, in the second direction D2, a top surface of the isolation structure 23 is located above a top surface of the conductive structure 17. The isolation structure 23 is disposed between adjacent conductive structures 17. On the one hand, adjacent conductive structures 17 may be electrically isolated to prevent signal crosstalk between the adjacent conductive structures 17. On the other hand, the isolation structure 23 is higher than the barrier layer 21 in the second direction D2, to prevent a position shift of the contact plug 25 electrically connected to the conductive structure 17 due to an oblique distortion or misalignment. In this way, a distance between the contact plug 25 electrically connected to one of the two adjacent conductive structures 17 in the first direction D1 and the other conductive structure 17 is increased, thereby reducing leakage issues between the contact plug 25 electrically connected to one of the conductive structures 17 and the other conductive structure 17.

In some embodiments, a bottom surface of the contact plug 25 is in electrical contact connection with a top surface of the conductive structure 17.

The width of the contact plug 25 is less than the width of the gap between the two adjacent isolation structures 23.

For example, as shown in FIG. 1, the bottom surface of the contact plug 25 is in electrical contact connection with the top surface of the conductive structure 17 directly, and the width of the contact plug 25 in the first direction D1 is less than the width of the gap between the two adjacent isolation structures 23 in the first direction D1, that is, there is a gap between the contact plug 25 and the isolation structure 23. This helps further increase a distance between the contact plug 25 electrically connected to one of the conductive structures 17 and another conductive structure 17, thereby further reducing a leakage current within the semiconductor structure.

In some embodiments, a projection of the contact plug 25 on a top surface of the substrate 10 is located within a projection of the gap between two adjacent isolation structures 23 on the top surface of the substrate 10. In this case, there is a gap between the contact plug 25 and the isolation structure 23 adjacent to the contact plug 25, so as to reserve specific space for shift of the contact plug 25 in a manufacturing process, and further reduce short circuits between adjacent contact plugs 25 and between the contact plug 25 and a surrounding conductive structure 17.

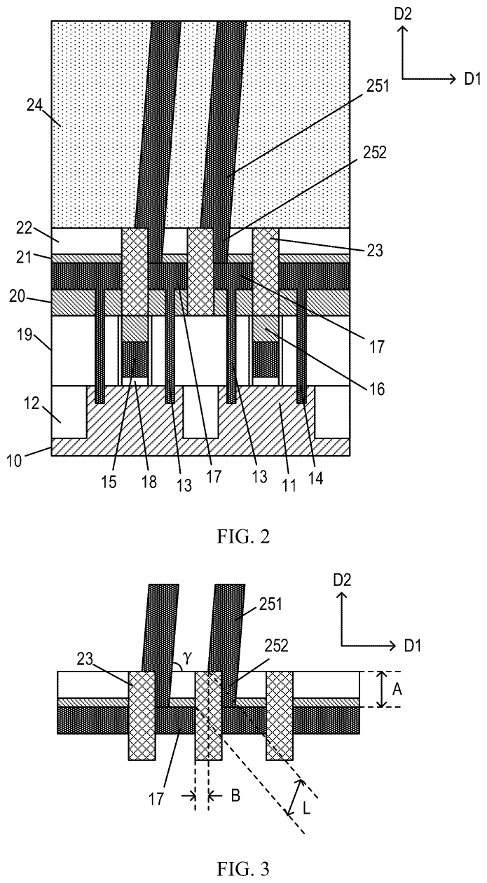

FIG. 2 is another schematic structural diagram of a semiconductor structure according to a specific implementation of the present disclosure. FIG. 3 is a schematic diagram of a relative position relationship between a contact plug, a conductive structure, and an isolation structure in FIG. 2. In some embodiments, as shown in FIG. 2 and FIG. 3, the contact plug 25 includes:
a first portion 251 located on the isolation structure 23, the first portion 251 covering at least a part of a top surface of the isolation structure 23; and
a second portion 252 protruding over a bottom surface of the first portion 251, the second portion 252 covering a sidewall of the isolation structure 23 and the top surface of the conductive structure 17.

In some embodiments, the width of the second portion 252 is less than the width of the first portion 251, and a part of a sidewall of the second portion 252 is flush with a part of a sidewall of the first portion 251.

In some embodiments, the contact plug 25 extends in a direction in which the substrate 10 points to the conductive structure 17; or
an extension direction of the contact plug 25 obliquely intersects the direction in which the substrate 10 points to the conductive structure 17.

In an example, the direction in which the substrate 10 points to the conductive structure 17 may be the second direction D2 in FIG. 1 and FIG. 2.

In an example, a ratio of a height of the contact plug 25 in the second direction D2 to the width of the contact plug 25 in the first direction D1 (i.e., an aspect ratio of the contact plug 25) is greater than or equal to 100:1. Because the contact plug 25 has a high aspect ratio, the actually formed contact plug 25 extends in the third direction, and an included angle between the third direction and the second direction D2 is γ, as shown in FIG. 3. For two adjacent conductive structures 17 in the first direction D1, when a distance between the top surface of the isolation structure 23 and the bottom surface of one of the conductive structures 17 is a first distance A, and a distance between an edge of a projection of the contact plug 25 electrically connected to one of the conductive structures 17 on the top surface of the substrate 10 and an edge of a projection of the other conductive structure 17 on the top surface of the substrate 10 is a second distance B, a distance L between the contact plug 25 electrically connected to one of the conductive structures 17 and the other conductive structure 17 is (A²+B²)^{1/2}. It can be learned from the foregoing description that, even if the contact plug 25 electrically connected to one of the conductive structures 17 is distorted or shifted, a large distance can be maintained between the contact plug 25 and the conductive structure 17 adjacent to the contact plug 25, thereby reducing leakage issues within the semiconductor structure and improving performance of the semiconductor structure.

In some embodiments, a distance between the top surface of the isolation structure 23 and the top surface of the conductive structure 17 is 10 nm to 100 nm in the direction in which the substrate 10 points to the conductive structure 17, thereby effectively reducing the distance between the contact plug 25 and the surrounding conductive structure 17, and avoiding an excessive size of the semiconductor structure. In an example, the distance between the top surface of the isolation structure 23 and the top surface of the conductive structure 17 is 40 nm.

In some embodiments, the semiconductor structure further includes:
an isolation layer disposed on the barrier layer 21.

The contact plug 25 continuously penetrates the isolation layer and the barrier layer 21.

In some embodiments, the isolation layer is of a single-layer structure. In an example, the isolation layer is made of an oxide material, such as silicon dioxide.

In some other embodiments, the isolation layer includes:
a first isolation layer 22 located on the barrier layer 21; and
a second isolation layer 24 located on the first isolation layer 22, the thickness of the first isolation layer 22 being less than the thickness of the second isolation layer 24, and the thickness of the first isolation layer 22 being greater than or equal to the thickness of the barrier layer 21.

In some embodiments, the barrier layer 21 is made of a nitride material.

Specifically, as shown in FIG. 1 or FIG. 2, the contact plug 25 penetrates the barrier layer 21, the first isolation layer 22, and the second isolation layer 24 in the second direction D2. On the one hand, the isolation layer can protect the conductive structure 17, reducing impact of a subsequent process on the conductive structure 17. On the other hand, the isolation layer further helps simplify the formation process of the isolation structure 23. In an example, the thickness of the barrier layer 21 in the second direction D2 is 10 nm, and the thickness of the first isolation layer 22 in the second direction D2 is 30 nm.

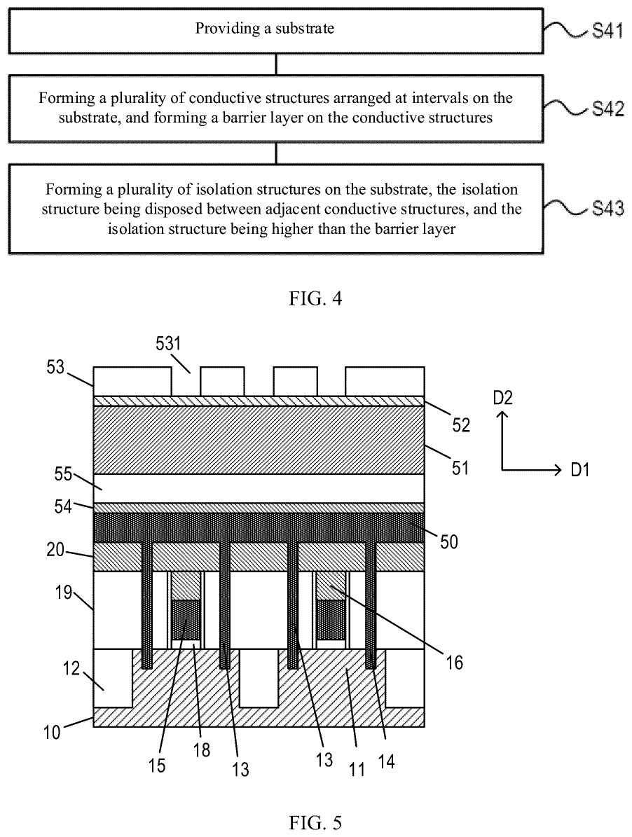

A specific implementation further provides a method for forming a semiconductor structure. FIG. 4 is a flowchart of a method for forming a semiconductor structure according to a specific implementation of the present disclosure. FIG. 5 to FIG. 10 are schematic cross-sectional views of main techniques in a process of forming a semiconductor structure according to a specific implementation of the present disclosure. For a schematic diagram of the semiconductor structure formed in this specific implementation, reference may be made to FIG. 1 to FIG. 3. As shown in FIG. 1 to FIG. 10, the method for forming a semiconductor structure includes the steps as follows.

In the step of S41, a substrate 10 is provided.

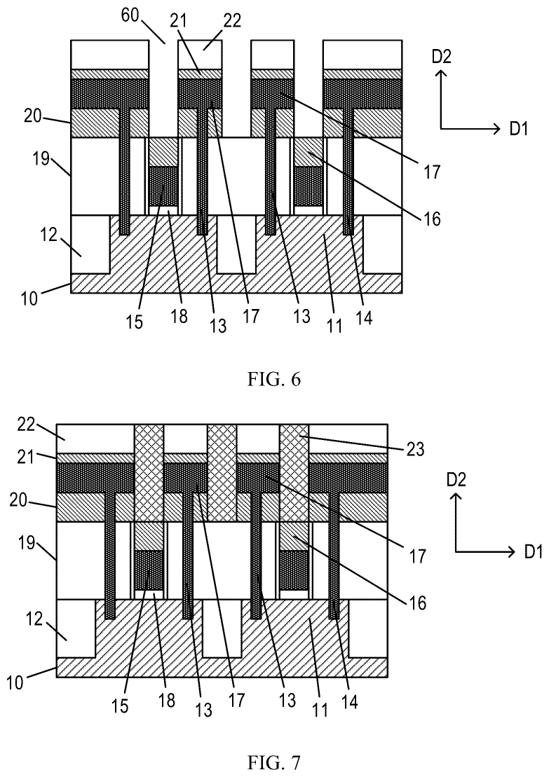

In the step of S42, multiple conductive structures 17 arranged at intervals are formed on the substrate 10, and a barrier layer 21 is formed on the conductive structures 17, as shown in FIG. 6.

In the step of S43, multiple isolation structures 23 are formed on a top surface of the substrate 10. The isolation structure 23 is disposed between adjacent conductive structures 17, and the isolation structure 23 is higher than the barrier layer 21, as shown in FIG. 7.

In some embodiments, the step in which multiple conductive structures 17 are formed on the substrate 10, and a barrier layer 21 is formed on the conductive structures 17 includes the specific steps as follows.

A conductive material layer 50 covering the top surface of the substrate 10 is formed, as shown in FIG. 5.

An initial barrier layer 54 covering the conductive material layer 50 is formed, as shown in FIG. 5.

The initial barrier layer 54 and the conductive material layer 50 are etched to form multiple first trenches 60 arranged at intervals in a first direction D1 and penetrating the conductive material layer 50 and the initial barrier layer 54 in a second direction D2. The multiple first trenches 60 separate the conductive material layer 50 into multiple independent conductive structures 17 arranged at intervals in the first direction D1, and separate the initial barrier layer 54 into multiple independent barrier layers 21 arranged at intervals in the first direction D1, the first direction D1 is parallel to the top surface of the substrate 10, and the second direction D2 is perpendicular to the top surface of the substrate 10, as shown in FIG. 6.

In some embodiments, that multiple first trenches 60 arranged at intervals in a first direction D1 and penetrating the conductive material layer 50 and the initial barrier layer 54 in a second direction D2 are formed includes the specific steps as follows.

An initial first isolation layer 55 covering a top surface of the initial barrier layer 54 is formed, as shown in FIG. 5.

The initial first isolation layer 55, the initial barrier layer 54, and the conductive material layer 50 are etched to form the first trenches 60 continuously penetrating the initial first isolation layer, the initial barrier layer 54, and the conductive material layer 50 in the second direction D2. The multiple first trenches 60 separate the initial first isolation layer 55 into multiple independent first isolation layers 22 arranged at intervals in the first direction D1.

In some embodiments, the thickness of the initial first isolation layer 55 in the second direction D2 is greater than or equal to the thickness of the initial barrier layer 21 in the second direction D2.

In some embodiments, the initial first isolation layer 55 is made of an oxide material and the initial barrier layer 54 is made of a nitride material.

In some embodiments, the total thickness of the initial first isolation layer 55 and the initial barrier layer 54 in the second direction D2 is 10 nm to 100 nm.

For example, the substrate 10 includes at least multiple active regions 11 arranged at intervals in the first direction D1 and a shallow trench isolation region 12 located between adjacent active regions 11, and the shallow trench isolation region 12 is configured to electrically isolate adjacent active regions 11. The active region 11 includes a channel region, and a source region and a drain region that are located on two opposite sides of the channel region in the first direction D1. The top surface of the substrate 10 further has a word line structure, and a first contact pillar 13 and a second contact pillar 14 that are located on two opposite sides of the word line structure in the first direction D1. The word line structure includes a gate dielectric layer 18 covering a top surface of the channel region, a word line conductive layer 15 located on a top surface of the gate dielectric layer 18, and a word line cap layer 16 located on a top surface of the word line conductive layer 15. The first contact pillar 13 is in electrical contact connection with the source region, and the second contact pillar 14 is in electrical contact connection with the drain region. For two adjacent active regions in the substrate 10 in the first direction D1, the drain region in one active region is adjacent to the drain region in the other active region. The substrate 10 further includes a first dielectric layer 19 covering the first contact pillar 13, the second contact pillar 14, and the word line structure, and a second dielectric layer 20 covering a top surface of the first dielectric layer 19.

After the conductive material layer 50 covering the top surface of the substrate 10 is formed, an insulation material such as nitride may be deposited on the top surface of the second dielectric layer 20 through an atomic layer deposition process to form the initial barrier layer 54. Then, an insulation material such as oxide is deposited on the top surface of the initial barrier layer 54 through the atomic layer deposition process to form the initial first isolation layer 55. A first mask layer 51, a second mask layer 52 located on a top surface of the first mask layer 51, and a third mask layer 53 located on a top surface of the second mask layer 52 are sequentially formed on the top surface of the initial first isolation layer 55, and the third mask layer 53 has a first opening 531 exposing the second mask layer 52, as shown in FIG. 5. The second mask layer 52, the first mask layer 51, the initial first isolation layer 55, the initial barrier layer 54, the conductive material layer 50, and at least a part of the second dielectric layer 20 are etched downward along the first opening 531 to form the first trench 60. After the third mask layer 53, the second mask layer 52, and the first mask layer 51 are removed, a structure shown in FIG. 6 is obtained.

After the conductive material layer 50 is etched and the conductive structure 17 is formed, the barrier layer 21 can protect the conductive structure 17, preventing oxidation and electrochemical reaction from occurring on the conductive structure. In addition, the barrier layer 21 can further function as a part of the etch barrier layer in a subsequent process of forming a through-hole 90 through etching. The thickness of the barrier layer 21 cannot be too large. A problem such as under-etch of the through-hole 90 or an excessively small feature size of the bottom of the through-hole 90 may easily occur when the barrier layer 21 is too thick. Consequently, a subsequently formed contact plug is in poor electrical contact with the conductive structure. In an example, the thickness of the initial first isolation layer 55 in the second direction D2 is 30 nm, and the thickness of the initial barrier layer 21 in the second direction D2 is 10 nm.

In some embodiments, the step in which multiple isolation structures 23 are formed on the substrate 10 includes the specific step as follows.

The multiple first trenches 60 are filled with an insulation material to form the multiple isolation structures 23 one by one in the multiple first trenches 60. A top surface of the isolation structure 23 is flush with a top surface of the first isolation layer 22 or a top surface of the isolation structure 23 is higher than a top surface of the first isolation layer 22.

In some embodiments, that the multiple isolation structures 23 are formed one by one in the multiple first trenches 60 includes the specific steps as follows.

The insulation material continuously and fully filling the multiple first trenches 60 and covering the top surface of the first isolation layer 22 is formed.

The insulation material covering the top surface of the first isolation layer 22 is removed, and the insulation material is retained in the first trenches 60 as the isolation structure 23, as shown in FIG. 7.

In some embodiments, after the multiple isolation structures 23 are formed on the substrate 10, the method further includes the step as follows.

Multiple contact plugs 25 in a one-to-one correspondence with the multiple conductive structures 17 are formed. The contact plug 25 at least partially runs through a gap between two adjacent isolation structures 23 and is electrically connected to the conductive structure 17.

In some embodiments, the step in which multiple contact plugs 25 in a one-to-one correspondence with the multiple conductive structures 17 are formed includes the specific steps as follows.

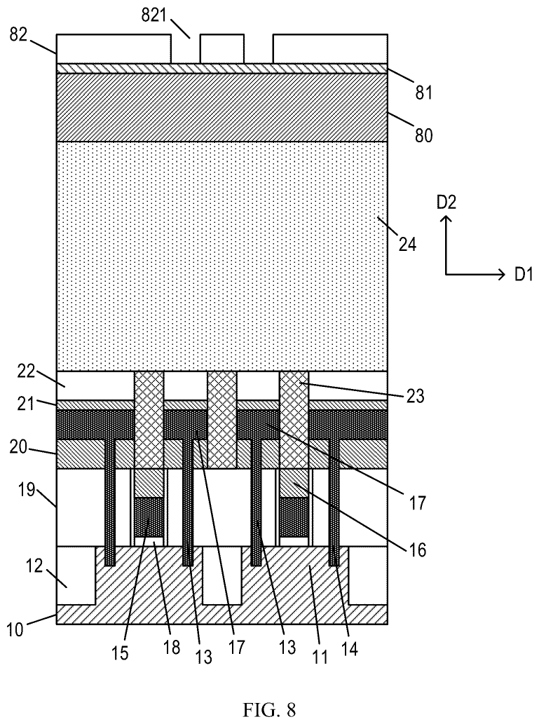

A second isolation layer 24 covering a top surface of the isolation structure 23 and a top surface of the first isolation layer 22 is formed, as shown in FIG. 8.

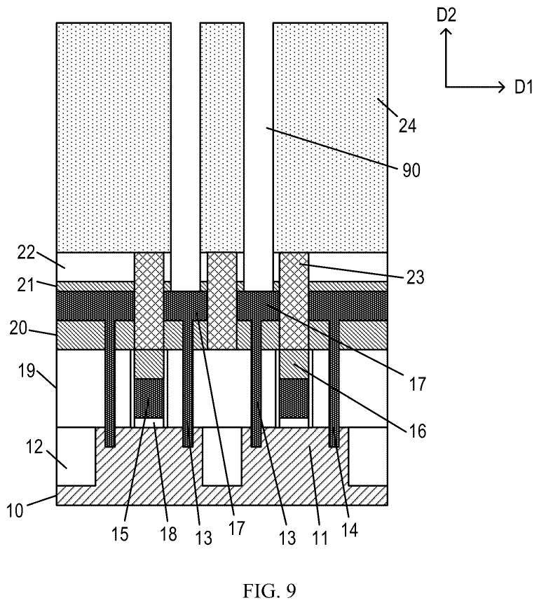

A through-hole 90 penetrating at least the second isolation layer 24, the first isolation layer 22, and the barrier layer 21 in the second direction D2 is formed. A bottom of the through-hole 90 exposes the conductive structure 17, as shown in FIG. 9.

The contact plug 25 fully filling the through-hole 90 is formed.

In some embodiments, the through-hole 90 exposes the top surface of the conductive structure 17 or the through-hole 90 extends to an interior of the conductive structure 17.

The width of the through-hole 90 is less than the width of the gap between the two adjacent isolation structures 23.

In some embodiments, a bottom surface of the through-hole 90 is flat, and a projection of the through-hole 90 on the top surface of the substrate 10 is located within a projection of the gap between two adjacent isolation structures 23 on the top surface of the substrate 10, as shown in FIG. 1.

In some embodiments, the through-hole 90 extends in the second direction D2; or
the through-hole 90 extends in a third direction, and the third direction obliquely intersects the second direction D2.

For example, after the isolation structure 23 is formed in the first trench 60, an insulation material such as oxide is deposited on the top surface of the first isolation layer 22 and the top surface of the isolation structure 23 to form the second isolation layer 24. Next, a fourth mask layer 80 is formed on a top surface of the second isolation layer 24, a fifth mask layer 81 is formed on a top surface of the fourth mask layer 80, a sixth mask layer 82 is formed on a top surface of the fifth mask layer 81, and the sixth mask layer 82 has a second opening 821 exposing the fifth mask layer 81, as shown in FIG. 8. At least the fifth mask layer 81, the fourth mask layer 80, the second isolation layer 24, the first isolation layer 22, and the barrier layer 21 are etched downward along the second opening 821 to form the through-hole 90 exposing the conductive structure 17. After the sixth mask layer 82, the fifth mask layer 81, and the fourth mask layer 80 are removed, a structure shown in FIG. 9 is obtained. Then, a conductive material such as metal tungsten is deposited in the through-hole 90 to form the contact plug 25, as shown in FIG. 1. When morphology of the through-hole 90 is not distorted and a position of the through-hole 90 is aligned with a preset position, a projection of the through-hole 90 on the top surface of the substrate 10 is located within a projection of the gap between two adjacent isolation structures 23 in the first direction D1 on the top surface of the substrate 10.

In some embodiments, the step in which a through-hole penetrating at least the second isolation layer 24, the first isolation layer 22, and the barrier layer 21 in the second direction D2 is formed includes the specific step as follows.

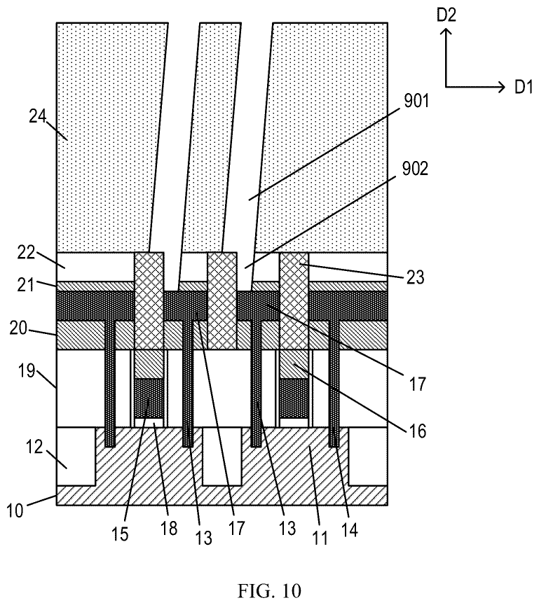

The second isolation layer 24, the first isolation layer 22, and the barrier layer 21 are etched to form the through-hole including a first sub-through-hole 901 and a second sub-through-hole 902. A bottom surface of the first sub-through-hole 901 exposes the top surface of the isolation structure 23, the second sub-through-hole 902 protrudes over the bottom surface of the first sub-through-hole 901 in the second direction D2 and is in communication with the first sub-through-hole 901, and the second sub-through-hole 902 exposes a sidewall of the isolation structure 23 and the conductive structure 17, as shown in FIG. 10.

In some embodiments, the width of the first sub-through-hole 901 is greater than the width of the second sub-through-hole 902, and a part of a sidewall of the second sub-through-hole 902 is flush with a part of a sidewall of the first sub-through-hole 901.

Specifically, because the through-hole has a high aspect ratio (that is, a ratio of a height of the through-hole in the second direction D2 to the width of the through-hole in the first direction D1), in the process of etching the second isolation layer 24, the first isolation layer 22, and the barrier layer 21, the through-hole may encounter a problem such as an oblique distortion or a position shift. In this case, the through-hole is inclined relative to the second direction D2, and as a result, the formed through-hole includes the first sub-through-hole 901 and the second sub-through-hole 902. Then, the first sub-through-hole 901 and the second sub-through-hole 902 are filled with a conductive material such as metal tungsten to form the contact plug including the first portion 251 and the second portion 252, as shown in FIG. 2.

According to the semiconductor structure and the method for forming the same provided in some embodiments of this specific implementation, multiple independent isolation structures arranged at intervals are disposed on the top surface of the substrate, each of the isolation structures is located between two adjacent conductive structures, and the isolation structure is higher than a barrier layer disposed on the conductive structure, so that when a contact plug electrically connected to the conductive structure is formed, a position shift of the contact plug caused by misalignment or a distortion can be reduced through the isolation structure. In this way, a distance between the contact plug electrically connected to one of the two adjacent conductive structures and the other conductive structure is increased, thereby reducing leakage issues between the contact plug electrically connected to one of the conductive structures and the other conductive structure, and further reducing burn-out of the semiconductor structure and improving performance and yield of the semiconductor structure.

The foregoing descriptions are merely example implementations of the present disclosure. It should be noted that a person of ordinary skill in the art may make several improvements or polishing without departing from the principle of the present disclosure and the improvements or polishing shall fall within the protection scope of the present disclosure.

What is claimed is:

1. A semiconductor structure, comprising:
a substrate;
a plurality of conductive structures, the plurality of conductive structures being arranged at intervals on the substrate;
a plurality of isolation structures, the isolation structure being disposed between adjacent conductive structures; and
a barrier layer, the barrier layer being disposed on the conductive structure, and
the isolation structure being higher than the barrier layer.

2. The semiconductor structure according to claim 1, further comprising:
a plurality of contact plugs, the plurality of contact plugs being in a one-to-one correspondence with the plurality of conductive structures, and the contact plugs running through a gap between two adjacent isolation structures and being electrically connected to the conductive structures.

3. The semiconductor structure according to claim 1, wherein a bottom surface of a contact plug is in electrical contact connection with a top surface of the conductive structure; and
a width of the contact plug is less than a width of a gap between the two adjacent isolation structures.

4. The semiconductor structure according to claim 3, wherein a projection of a contact plug on a top surface of the substrate is located within a projection of a gap between two adjacent isolation structures on the top surface of the substrate.

5. The semiconductor structure according to claim 2, wherein the contact plug comprises:
a first portion located on the isolation structure, the first portion covering at least a part of a top surface of the isolation structure; and
a second portion protruding over a bottom surface of the first portion, the second portion covering a sidewall of the isolation structure and the top surface of the conductive structure.

6. The semiconductor structure according to claim 5, wherein a width of the second portion is less than a width of the first portion, and a part of a sidewall of the second portion is flush with a part of a sidewall of the first portion.

7. The semiconductor structure according to claim 4, wherein a contact plug extends in a direction in which the substrate points to the conductive structure; or
an extension direction of the contact plug obliquely intersects the direction in which the substrate points to the conductive structure.

8. The semiconductor structure according to claim 1, wherein a distance between a top surface of the isolation structure and the top surface of the conductive structure is 10 nm to 100 nm in a direction in which the substrate points to the conductive structure.

9. The semiconductor structure according to claim 2, further comprising:
an isolation layer disposed on the barrier layer;
the contact plug continuously penetrating the isolation layer and the barrier layer.

10. The semiconductor structure according to claim 1, wherein the barrier layer is made of a nitride material.

11. A method for forming a semiconductor structure, comprising the following steps:
providing a substrate;
forming a plurality of conductive structures arranged at intervals on the substrate, and forming a barrier layer on the conductive structures; and
forming a plurality of isolation structures on the substrate, the isolation structure being disposed between adjacent conductive structures, and the isolation structure being higher than the barrier layer.

12. The method for forming a semiconductor structure according to claim 11, wherein the forming a plurality of conductive structures arranged at intervals on the substrate, and forming a barrier layer on the conductive structures comprises the following specific steps:
forming a conductive material layer covering a top surface of the substrate;
forming an initial barrier layer covering the conductive material layer; and
etching the initial barrier layer and the conductive material layer to form a plurality of first trenches arranged at intervals in a first direction and penetrating the conductive material layer and the initial barrier layer in a second direction, the plurality of first trenches separating the conductive material layer into a plurality of independent conductive structures arranged at intervals in the first direction, and separating the initial barrier layer into a plurality of independent barrier layers arranged at intervals in the first direction, the first direction being parallel to the top surface of the substrate, and the second direction being perpendicular to the top surface of the substrate.

13. The method for forming a semiconductor structure according to claim 12, wherein the forming a plurality of first trenches arranged at intervals in a first direction and penetrating the conductive material layer and the initial barrier layer in a second direction comprises the following specific steps:
forming an initial first isolation layer covering a top surface of the initial barrier layer; and
etching the initial first isolation layer, the initial barrier layer, and the conductive material layer to form the first trenches continuously penetrating the initial first isolation layer, the initial barrier layer, and the conductive material layer in the second direction, the plurality of first trenches separating the initial first isolation layer into a plurality of independent first isolation layers arranged at intervals in the first direction.

14. The method for forming a semiconductor structure according to claim 13, wherein a thickness of the initial first isolation layer in the second direction is greater than or equal to a thickness of the initial barrier layer in the second direction;
wherein the initial first isolation layer is made of an oxide material and the initial barrier layer is made of a nitride material; and
wherein a total thickness of the initial first isolation layer and the initial barrier layer in the second direction is 10 nm to 100 nm.

15. The method for forming a semiconductor structure according to claim 13, wherein the forming a plurality of isolation structures on the substrate comprises the following specific steps:
filling the plurality of first trenches with an insulation material to form the plurality of isolation structures one by one in the plurality of first trenches, a top surface of the isolation structure being flush with a top surface of the first isolation layer or a top surface of the isolation structure being higher than a top surface of the first isolation layer.

16. The method for forming a semiconductor structure according to claim 15, wherein the forming the plurality of isolation structures one by one in the plurality of first trenches comprises the following specific steps:
forming the insulation material continuously and fully filling the plurality of first trenches and covering the top surface of the first isolation layer; and
removing the insulation material covering the top surface of the first isolation layer, and retaining the insulation material in the first trenches as the isolation structure.

17. The method for forming a semiconductor structure according to claim 13, after the forming a plurality of isolation structures on the substrate, further comprising the following steps:
forming a plurality of contact plugs in a one-to-one correspondence with the plurality of conductive structures, the contact plug at least partially running through a gap between two adjacent isolation structures and being electrically connected to the conductive structure.

18. The method for forming a semiconductor structure according to claim 17, wherein the forming a plurality of contact plugs in a one-to-one correspondence with the plurality of conductive structures comprises the following specific steps:
forming a second isolation layer covering a top surface of the isolation structure and a top surface of the first isolation layer;
forming a through-hole penetrating at least the second isolation layer, the first isolation layer, and the barrier layer in the second direction, a bottom of the through-hole exposing the conductive structure; and
forming the contact plug fully filling the through-hole.

19. The method for forming a semiconductor structure according to claim 18, wherein the through-hole exposes the top surface of the conductive structure or the through-hole extends to an interior of the conductive structure; and
a width of the through-hole is less than a width of the gap between the two adjacent isolation structures;
wherein a bottom surface of the through-hole is flat, and a projection of the through-hole on the top surface of the substrate is located within a projection of the gap between two adjacent isolation structures on the top surface of the substrate.

20. The method for forming a semiconductor structure according to claim 18, wherein the through-hole extends in the second direction; or
the through-hole extends in a third direction, and the third direction obliquely intersects the second direction;
wherein the forming a through-hole penetrating at least the second isolation layer, the first isolation layer, and the barrier layer in the second direction comprises the following specific steps:
etching the second isolation layer, the first isolation layer, and the barrier layer to form the through-hole comprising a first sub-through-hole and a second sub-through-hole, a bottom surface of the first sub-through-hole exposing the top surface of the isolation structure, the second sub-through-hole protruding over the bottom surface of the first sub-through-hole in the second direction and being in communication with the first sub-through-hole, and the second sub-through-hole exposing a sidewall of the isolation structure and the conductive structure; and
wherein a width of the first sub-through-hole is greater than a width of the second sub-through-hole, and a part of a sidewall of the second sub-through-hole is flush with a part of a sidewall of the first sub-through-hole.
